(19) United States
(12) Patent Application Publication
(10) Pub. No.: US 2018/0350607 A1
(43) Pub. Date: Dec. 6, 2018

(54) SEMICONDUCTOR STRUCTURE

(71) Applicant: GLOBALFOUNDRIES INC., GRAND CAYMAN (KY)

(72) Inventors: Jiehui SHU, Clifton Park, NY (US); Haifeng SHENG, Rexford, NY (US); Jinping LIU, Ballston Lake, NY (US)

(21) Appl. No.: 15/611,231

(22) Filed: Jun. 1, 2017

(51) Int. Cl. H01L 21/28; H01L 21/02; H01L 21/768; H01L 21/311

(52) U.S. Cl. CPC H01L 21/28247; H01L 21/02178; H01L 21/31122; H01L 21/76828; H01L 21/02362

(57) ABSTRACT

The present disclosure relates to semiconductor structures and, more particularly, to methods to remove a contact etch stop layer without consuming material of a self-aligned contact (SAC) layer. The method includes: forming a gate structure on a substrate; forming a capping layer on the gate structure; forming a contact etch stop layer of a first material, adjacent to the gate metal structure; converting the contact etch stop layer to a second material which is different than the capping layer; and selectively removing the second material without completely removing the capping layer.

### FIELD OF THE INVENTION

The present disclosure relates to semiconductor structures and, more particularly, to methods to remove a contact etch stop layer without consuming material of a self-aligned contact (SAC) layer.

### BACKGROUND

Fabricating smaller, more densely packed devices having greater computing capability is a continuing objective in building semiconductor devices. One solution to this problem is the implementation of FinFET technologies. FinFETs provide superior levels of scalability and increased levels of integration within integrated circuits. The FinFET, for example, also provides improved electrical control over the channel conduction and reduced leakage current levels. In addition, FinFETs can provide lower power consumption which allows high integration levels, operation at lower voltage as a result of their lower threshold voltage and, often, increase operating speeds compared to planar devices.

However, as technology nodes become smaller, e.g., the FinFET scales down, it becomes more challenging to fabricate such devices. For example, as the FinFET scales down, the device becomes more prone to shorting between trench silicide (e.g., metal contacts) and metal gate structures. This is due, at least partly, to the self-aligned capping material, which protects the metal gate structures, being consumed during etching and planarization processes leading to the metal contact fabrication. For example, it has been observed that the removal of a contact etch stop layer (CESL) can consume as much as 5 nm of the capping layer material. This, in turn, can expose the underlying metal gate material resulting in shorting of the device. In this way, it is critical to control etching processes and to ensure that the capping layer material does not become consumed during subsequent fabrication processes.

### SUMMARY

In an aspect of the disclosure, a method comprises: forming a gate structure on a substrate; forming a capping layer on the gate structure; forming a contact etch stop layer of a first material, adjacent to the gate metal structure; converting the contact etch stop layer to a second material which is different than the capping layer; and selectively removing the second material without completely removing the capping layer.

In an aspect of the disclosure, a method comprises: forming a gate structure over one or more fins; forming a capping layer directly on the gate structure; forming insulating material on sidewalls of the gate structure and capping layer; forming a contact etch stop layer over the insulating material of adjacent gate structures; forming a metal oxide material on the contact etch stop layer; converting the contact etch stop layer to a material which is different than the capping layer; and selectively removing the converted contact etch stop layer without completely removing the capping layer.

In an aspect of the disclosure, a method comprises: forming a plurality of gate structures comprising: depositing gate material and capping material over a fin structure; patterning the gate material and capping material; and depositing insulating material on sidewalls of the patterned gate material and capping material; and forming a contact etch stop layer comprising a nitride material within a space between the insulating material of adjacent gate structures; depositing a metal oxide material on vertical surfaces of the contact etch stop layer; converting the contact etch stop layer to an oxide based material; and selectively removing the converted second material without completely removing the capping layer.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a cross-sectional view of an incoming structure and respective fabrication processes in accordance with aspects of the present disclosure.

FIG. 2 shows a metal oxide layer formed over an etch stop layer, amongst other features, and respective fabrication processes in accordance with aspects of the present disclosure.

FIG. 3 shows the metal oxide layer over vertical surfaces of the etch stop layer, amongst other features, and respective fabrication processes in accordance with aspects of the present disclosure.

FIG. 4 shows an anneal of the metal oxide layer to convert the etch stop layer to an oxide material, amongst other features, and respective fabrication processes in accordance with aspects of the present disclosure.

FIG. 5 shows removal of oxide material, prior to contact formation, amongst other features, and respective fabrication processes in accordance with aspects of the present disclosure.

FIG. 6 shows a contact material in electrical contact with a source or drain region of a gate structure, amongst other features, and respective fabrication processes in accordance with aspects of the present disclosure.

### DETAILED DESCRIPTION

The present disclosure relates to semiconductor structures and, more particularly, to methods to remove a contact etch stop layer (CESL) without significantly consuming material of a self-aligned contact (SAC) layer. More specifically, the present disclosure provides a method of removing a contact etch stop layer (e.g., SiN) without material loss of a self-aligned contact (SAC) material, which result in shorting of the device). Advantageously, by implementing aspects of the present disclosure, it is now possible to provide contacts (trench silicides) on source/drain regions of a gate structure without shorting with metal material of the gate structure.

In embodiments, the method can selectively etch vertically aligned converted nitride films, while not consuming (e.g., removing material that would result in a short of the device with contact material) an SiN SAC material during other processing steps, such as reactive ion etching (RIE) and chemical mechanical polishing (CMP) steps. The method includes, for example, planarizing an integrated circuit structure composed of vertically and horizontally aligned nitride films, following by depositing a film of metal oxide. The metal oxide can act as a catalyst to convert the nitride films into an oxide based material. The metal oxide can be planarized so that it covers only the vertically aligned nitride films. An anneal process is then performed which converts the SiN film covered by metal oxide to SiO₂. The SiO₂ can then be selectively etched without any masking materials and without consuming other materials, e.g., nitride capping layer (e.g., removing material of the nitride capping layer that would result in a short with contact material).

The structure of the present disclosure can be manufactured in a number of ways using a number of different tools. In general, though, the methodologies and tools are used to form structures with dimensions in the micrometer and nanometer scale. The methodologies, i.e., technologies, employed to manufacture the structure of the present disclosure have been adopted from integrated circuit (IC) technology. For example, the structures are built on wafers and are realized in films of material patterned by photolithographic processes on the top of a wafer. In particular, the fabrication of the structure uses three basic building blocks: (i) deposition of thin films of material on a substrate, (ii) applying a patterned mask on top of the films by photolithographic imaging, and (iii) etching the films selectively to the mask.

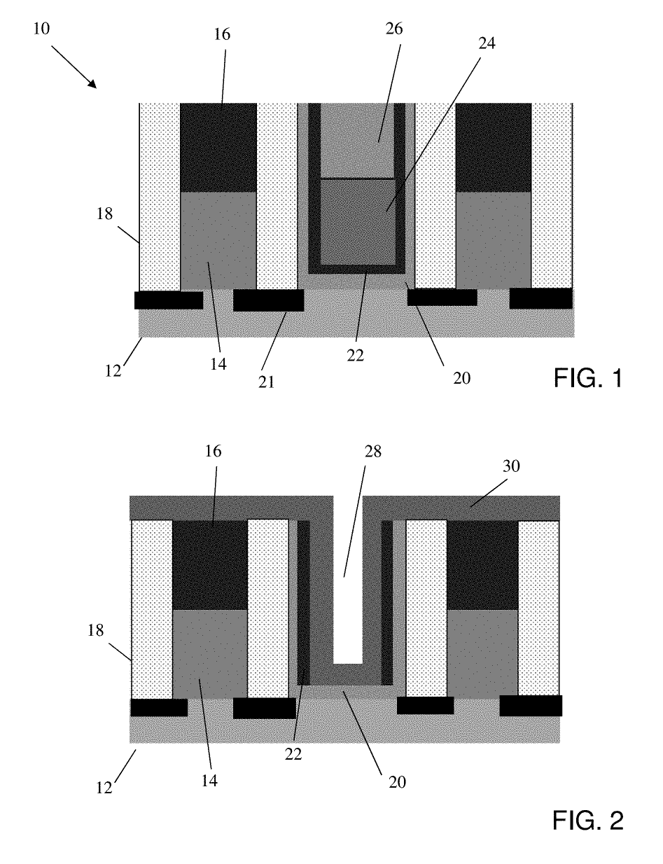

FIG. 1 shows a cross-sectional view of an incoming structure in accordance with aspects of the present disclosure. In embodiments, the structure 10 includes a fin structure 12 composed of a semiconductor material. The semiconductor material may be composed of any suitable material including, but not limited to, Si, SiGe, SiGeC, SiC, GaAs, InAs, InP, and other III/V or II/VI compound semiconductors.

In embodiments, the fin structure 12 can be formed by conventional lithography and etching processes or, alternatively, a sidewall image transfer (SIT) technique. In an example of a SIT technique, a mandrel material, e.g., SiO₂, is deposited on the semiconductor material using a conventional chemical vapor deposition (CVD) process. A resist is formed on the mandrel material, and exposed to light to form a pattern (openings). A reactive ion etching is performed through the openings to form the mandrels. Spacers are formed on the sidewalls of the mandrels which are preferably material that is different than the mandrels, and which are formed using conventional deposition processes known to those of skill in the art. The spacers can have a width which matches the dimensions of the narrow fin structure 12, for example. The mandrels are removed or stripped using a conventional etching process, selective to the mandrel material. An etching is then performed within the spacing of the spacers to form the sub-lithographic features. The sidewall spacers can then be stripped.

Still referring to FIG. 1, one or more gate structures 14 are formed on the fin structure 12. In embodiments, the gate structures 14 can be composed of various materials including, e.g., a gate dielectric material, a workfunction metal and metal or metal alloy materials, as examples. In embodiments, the gate dielectric material can be a high-k dielectric gate material such as, e.g., hafnium based dielectrics. In further embodiments, examples of such high-k dielectrics include, but are not limited: Al₂O₃, Ta₂O₃, TiO₂, La₂O₃, SrTiO₃, LaAlO₃, ZrO₂, Y₂O₃, Gd₂O₃, and combinations including multilayers thereof. A capping layer 16, e.g., SiN, is deposited on the upper most gate material using conventional deposition processes. In embodiments, the capping layer is a self-aligned SiN contact (SAC). After the deposition processes, the gate structure 14 and capping layer 16 are patterned by, e.g., conventional lithography and RIE processes.

An insulating material 18 is formed on the sidewalls of the patterned gate structures 14 and capping layer 16. In embodiments, the insulating material 18 can be a low-k dielectric material which is deposited using a conventional blanket deposition process. Any insulating material on the surface of the capping layer 16 can be removed by a conventional CMP process. An opening is provided between the insulating material 18 between adjacent gate structures 14.

FIG. 1 further shows source and drain regions 21 formed on the fin structure 12, adjacent to the gate structures 14. In embodiments, the source and drain regions 21 can be formed by conventional in-situ doping or ion implantation process, prior to contact formation (as shown in FIG. 6). A dual contact etch stop layer (CESL) composed of a first material 20 and a second material 22 is formed in contact with the fin structure 12. In embodiments, the first material 20 is an oxide based material and the second material 22 is a nitride based material, e.g., SiN. The first material 20 and the second material 22 can be deposited in separate blanket deposition processes, e.g., CVD processes, to form a CESL. A semiconductor material 24, e.g., Si, and an insulating material 26, e.g., SiO₂, can be deposited on the second material 22, between adjacent gate structures 14. Any material 20, 22, 24, 26 deposited on the surface of the capping layer 16 can be removed by a conventional CMP process. In embodiments, a single CMP process can be used remove the all materials 18, 20, 22, 24, 26.

FIG. 2 shows a metal oxide layer formed over the contact etch stop layer, amongst other features, and respective fabrication processes in accordance with aspects of the present disclosure. More specifically, as shown in FIG. 2, the first material 24 and the second material 26 can be removed by a selective etching process, e.g., RIE with selective chemistries. In embodiments, the selective etching process can be an anisotropic etch which also removes a portion of the second material 22 on the bottom of the trench (e.g., opening or space) 28, exposing the material 20 on the bottom of the trench 28.

A metal oxide 30 is then deposited on the structure, and preferably within the trench 28 and on exposed portions of the materials 20, 22. In embodiments, the metal oxide 30 can be a conformally deposited layer of Al₂O₃, For example, the metal oxide 30 can be deposited using an atomic layer deposition (ALD) process, with the metal oxide 30 deposited to a thickness of about 2 nm to about 10 nm (or other thickness that, when annealed, will convert the underlying nitride material 24 into an oxide based material). It should be understood that the metal oxide 30 would have a selectivity with respect to conventional cleaning processes, e.g., wet clean processes such as RCA or Piranha solution.

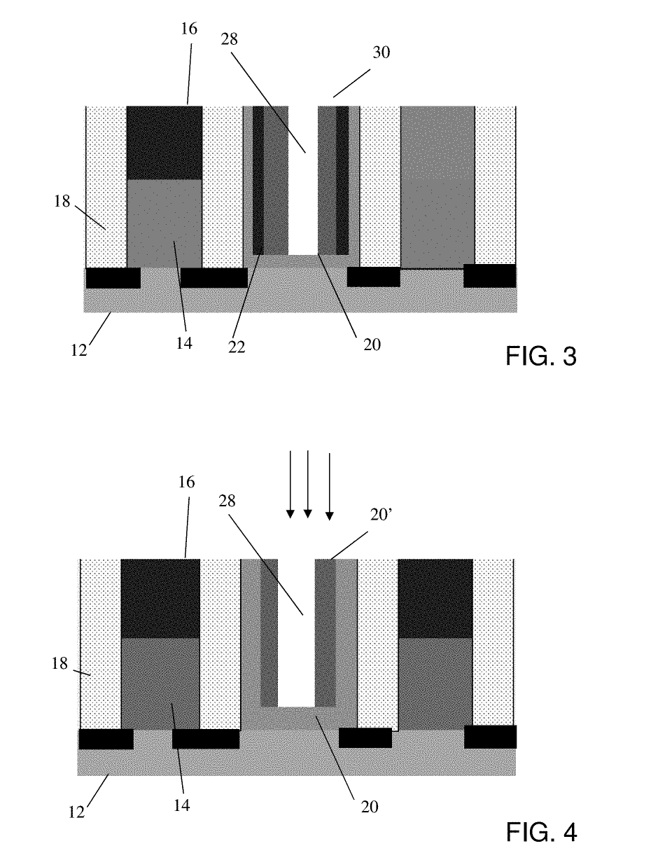

FIG. 3 shows the metal oxide layer over vertical surfaces of the contact etch stop layer, amongst other features, and respective fabrication processes in accordance with aspects of the present disclosure. More specifically, in FIG. 3, the metal oxide 30 is planarized, e.g., etched using an anisotropic etching process. In this way, the metal oxide 30 is removed from horizontal surfaces of the structure, covering only the vertically aligned nitride film, e.g., SiN layer (CESL) 22, on the sidewalls of the insulator material 18. It should be understood by those of skill in the art that the anisotropic etching process can be used to ensure coverage of the metal oxide 30 will remain on other vertical surfaces for subsequent oxidation, as needed in different devices.

In FIG. 4, the metal oxide 30 undergoes an anneal process which will convert the SiN layer (CESL) 22, covered by the metal oxide 30, to an SiO₂ layer 20′. In embodiments, the anneal process is a steam anneal process which can be conducted at a temperature of less than or equal to about 500° C. for less than one hour, as an example. As should be understood by those of skill in that art, during the steam anneal, there is an O₂ molecular exchange with the oxygen radical of the metal oxide, which will then diffuse into Si or SiN. This results in an oxidation of the underlying material, e.g., Si or SiN.

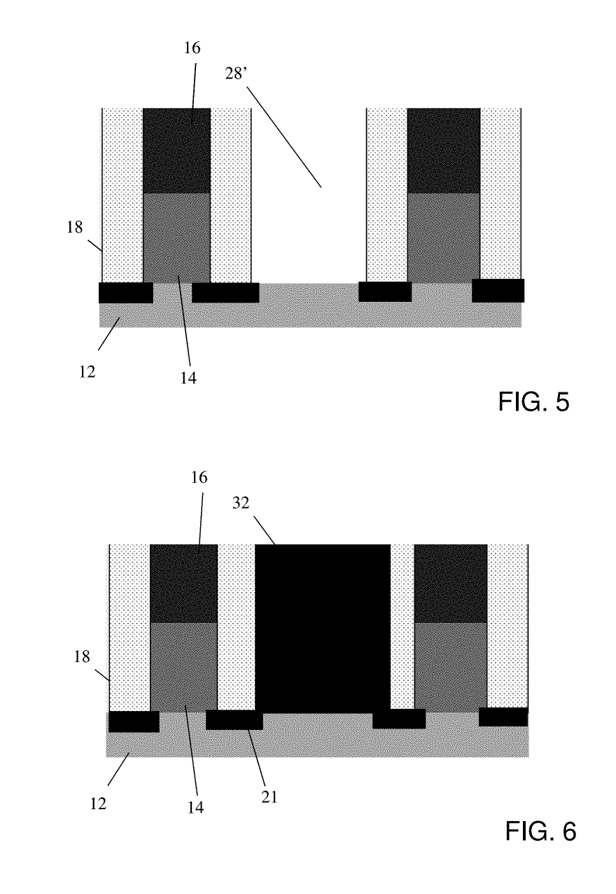

FIG. 5 shows removal of oxide material, prior to contact formation, amongst other features. For example, as shown in FIG. 5, the SiO₂ layer 20′ and oxide layer 20 can be selectively removed without any masking materials and without significantly consuming material, if any, of the self-aligned nitride capping layer (SAC) 16. That is, the removing of the SiO₂ layer 20′ and oxide layer 20 will not be remove (i.e., completely remove) the material of the self-aligned nitride capping layer 16 causing a short between gate metal material and metal contact material. This is due to the etching selectivity between the materials of the oxide material (oxygen containing materials) of layers 20, 20′ and the nitride material of the self-aligned capping layer 16. In embodiments, the removal process can be an etching process using a dHF etching chemistry. More specifically, a 100:1 dHF process can be used for about two minutes and preferably less than one minute to remove the layers 20, 20′. The structure can also undergo a standard clean process using NH₃ and H₂O, without consuming the self-aligned nitride capping layer 16. In this way, when a metal contact material (trench silicide) is deposited, the self-aligned nitride capping layer 16 will still be able to prevent shorting between the metal contact and the gate material 14.

FIG. 6 shows a contact material (trench silicide) 32, e.g., tungsten, in electrical contact with a source/drain region 21 of a gate structure 14. In embodiments, the SAC cap SiN layer 16 will be of sufficient thickness, e.g., 20 nm or thicker layer of SAC cap SiN material, to prevent any of the contact material from electrically shorting to the metal material of the gate structure 14. In embodiments, the contact material can be provided on a silicide region, in one embodiment.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A method, comprising:
forming a gate structure on a substrate;
forming a capping layer on the gate structure;
forming a contact etch stop layer of a first material, adjacent to the gate structure;
converting the contact etch stop layer to a second material which is different than the capping layer; and
selectively removing the second material without completely removing the capping layer.

2. The method of claim 1, wherein the converting the contact etch stop layer comprises forming a metal oxide material on the contact etch stop layer and subjecting the metal oxide material and the contact etch stop layer to an anneal process.

3. The method of claim 2, wherein the metal oxide material is Al₂O₃.

4. The method of claim 2, wherein the anneal process is a steam anneal.

5. The method of claim 2, wherein:
the capping layer and the first material are a nitride based material;
the second material is an oxygen containing material;
the substrate is a fin structure; and
the gate structure is a finFET gate structure.

6. The method of claim 5, wherein the second material is selectively removed without a mask and without consuming the capping layer.

7. The method of claim 1, wherein the converting the contact etch stop layer to the second material comprises:
forming the contact etch stop layer on sidewalls and on a bottom of an opening formed between adjacent to the gate metal structure;
etching the contact etch stop layer so that only vertical portions of the contact etch stop layer remain on the sidewalls of the opening;
depositing a metal oxide material on the contact etch layer; and
annealing the metal oxide material to convert the vertical portions of the contact etch stop layer into the second material.

8. The method of claim 7, wherein the depositing of the metal oxide material on the contact etch stop layer comprises depositing the metal oxide on both horizontal and vertical surfaces and further comprising planarizing the metal oxide material to remove it from horizontal surfaces so that it only covers the vertical portions of the contact etch stop layer on the sidewalls of the opening.

9. The method of claim 8, wherein the planarizing is performed prior to the anneal.

10. The method of claim 8, further comprising forming a contact structure within the opening, with the capping material preventing shorting occurring between metal material of the metal gate structure and the contact structure.

11. A method comprising:
forming a gate structure over one or more fins;
forming a capping layer directly on the gate structure;
forming insulating material on sidewalls of the gate structure and capping layer;
forming a contact etch stop layer over the insulating material of adjacent gate structures;
forming a metal oxide material on the contact etch stop layer;
converting the contact etch stop layer to a material different than the capping layer; and
selectively removing the converted contact etch stop layer without completely removing the capping layer.

12. The method of claim 11, wherein the converting comprises subjecting the metal oxide material and the contact etch stop layer to a steam anneal process.

13. The method of claim 12, wherein:
the capping layer and the contact etch stop layer prior to the converting are nitride based materials; and
the converted contact etch stop layer is an oxide based material.

14. The method of claim 13, wherein the converted contact etch stop layer is selectively removed without a mask and without consuming the capping layer.

15. The method of claim 11, wherein the forming a metal oxide material is a conformal deposition process depositing the metal oxide material on both horizontal and vertical surfaces, followed by an etching process to remove the metal oxide material on the horizontal surfaces, leaving the metal oxide material only on vertical surfaces of the converted contact etch stop layer.

16. The method of claim 15, wherein the etching process is performed prior to the converting.

17. The method of claim 16, further comprising forming a contact structure within the opening, with the capping material preventing shorting occurring between metal material of the metal gate structure and the contact structure.

18. A method comprising:
forming a plurality of gate structures comprising:
depositing gate material and capping material over a fin structure;
patterning the gate material and capping material; and
depositing insulating material on sidewalls of the patterned gate material and capping material; and
forming a contact etch stop layer comprising a nitride material within a space between the insulating material of adjacent gate structures;
depositing a metal oxide material on vertical surfaces of the contact etch stop layer;
converting the contact etch stop layer to an oxide based material; and
selectively removing the converted second material without completely removing the capping layer.

19. The method of claim 18, wherein the converting comprises subjecting the metal oxide material and the contact etch stop layer to a steam anneal process.

20. The method of claim 19, wherein the metal oxide material is Al₂O₃.
